(19) United States
(12) Patent Application Publication
(10) Pub. No.: US 2015/0276887 A1
(43) Pub. Date: Oct. 1, 2015

(54) METHOD AND APPARATUS OF ESTIMATING STATE OF HEALTH OF BATTERY

(71) Applicant: HON HAI PRECISION INDUSTRY CO., LTD., NEW TAIPEI (TW)

(72) Inventors: CHANG-YUAN SHIH, New Taipei (TW); HSIEN-HSI JUAN, New Taipei (TW)

(21) Appl. No.: 14/525,769

(22) Filed: Oct. 28, 2014

(30) Foreign Application Priority Data
Apr. 1, 2014 (TW) 103112203

(51) Int. Cl. G01R 31/36

(52) U.S. Cl. CPC G01R 31/3648; G01R 31/3606; G01R 31/3662

(57) ABSTRACT

A method of estimating state of health (SOH) of a battery includes measuring an internal resistance (R) of the battery and calculating a voltage drop (ΔV) value by a relationship of ΔV=R×I, wherein the I value is equal to a preset current lower limit value at the available capacity of the battery. Then measuring an open circuit voltage (OCV) lower limit value by the ΔV value and obtaining a state of charge lower limit (SOC_{—}1) from a correlation table of an OCV and a SOC of the battery. Finally, calculating a SOH value by a relationship of SOH=100%−SOC_{—}1. The present disclosure also discloses an apparatus for estimating SOH of a battery.

### FIELD

The subject matter herein generally relates to a method and apparatus of estimating a state of health (SOH) of a battery.

### BACKGROUND

A concept of state of health (SOH) is defined as an index for indicating the strength of a battery for electric vehicles, etc. The battery has an aging effect. The SOH detects a current state of the battery by predicting an aging degree in advance.

### BRIEF DESCRIPTION OF THE DRAWINGS

Implementations of the present technology will now be described, by way of example only, with reference to the attached figures.

FIG. 1 is a graph of a voltage following a current of a battery in discharge status.

FIG. 2 is a flow diagram of an embodiment of a method of estimating state of health (SOH) of a battery.

FIG. 3 is a correlation table of an open circuit voltage (OCV) and a state of charge (SOC) of the apparatus of estimating SOH of the battery of FIG. 2.

FIG. 4 is a diagram of an embodiment of an apparatus of estimating SOH of a battery.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The term “comprising,” when utilized, means “including, but not necessarily limited to”; it specifically indicates open-ended inclusion or membership in the so-described combination, group, series and the like.

The present disclosure is described in relation to a method and an apparatus for estimating state of health (SOH) of a battery.

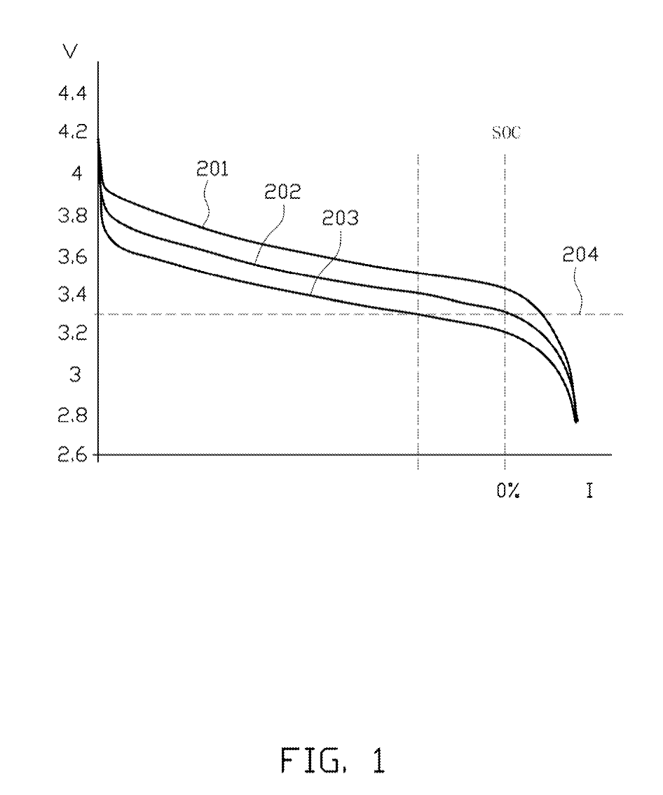

FIG. 1 illustrates graph of a voltage following a current of a battery in discharge status. For a new battery, a voltage lower limit 204 can be preset as a basis of the state of charge (SOC) dropping to 0% for setting a battery available capacity. The first curve 201 can illustrate a relationship of an open circuit voltage (OCV) value and a current of the battery. The second curve 202 can illustrate a relationship of terminal voltage value under designated current discharge status and a current of the battery. The third curve 203 can illustrate a relationship of terminal voltage value under designated current discharge status and a current of an aged battery. A voltage can reach the voltage lower limit 204 due to improving of the current and internal resistance of the battery. As a result, the battery available capacity can be dropped. A current lower limit can be preset for ensuring the battery available capacity. A voltage can reach the voltage lower limit 204 in the discharge status when a current is less than or equal to the preset current lower limit. Therefore, the SOC can be considered to have reached 0%.

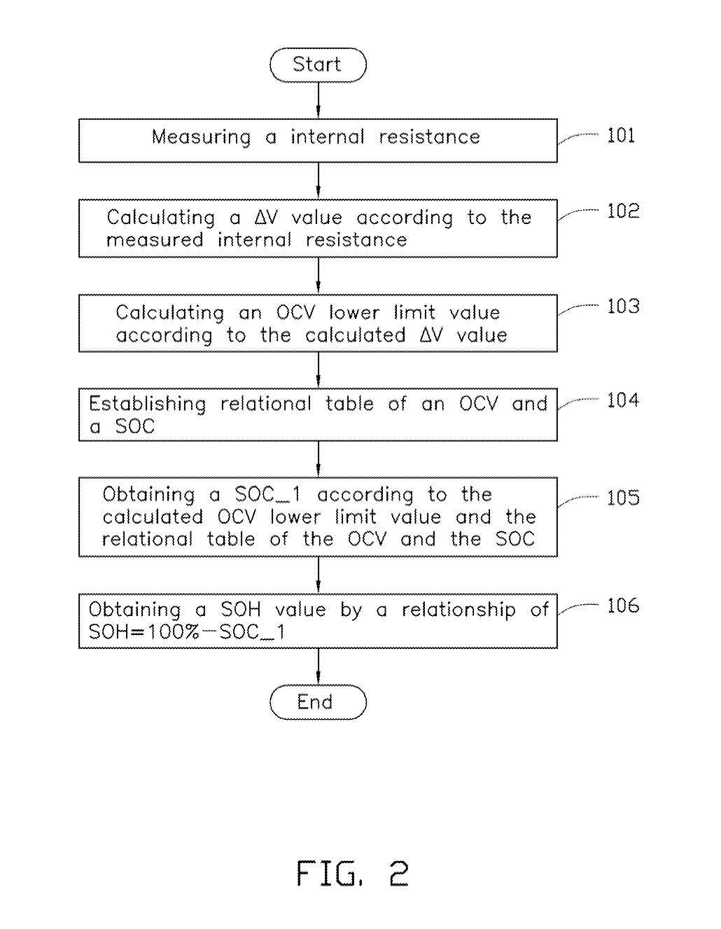

FIG. 2 illustrates a method of estimating SOH of a battery, which can include the following.

At block 101, an internal resistance (R) of a battery can be measured. A voltage value and a current value of the battery can be measured via a voltage sensing unit and a current sensing unit. The internal resistance can be calculated according to the measured current value and voltage value. The internal resistance can be also measured by an alternating current impedance method.

At block 102, a voltage drop (ΔV) can be calculated via multiplying the measured internal resistance by a preset current lower limit value (I) at the available capacity.

At block 103, an OCV lower limit value can be calculated via adding the ΔV and a voltage lower limit (V) at the available capacity.

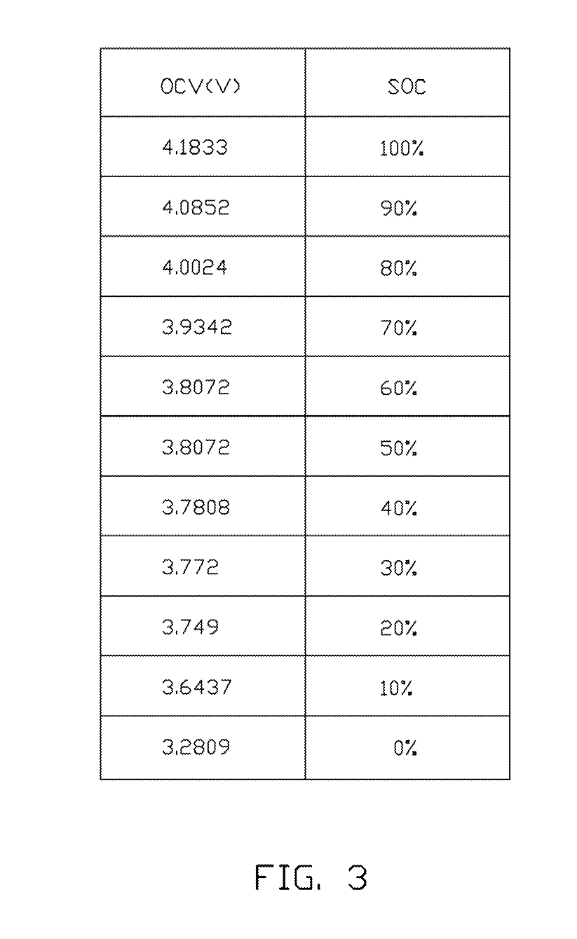

At block 104, a correlation table (shown in FIG. 3) of an OCV value and a SOC of battery can be established according to a plurality of raw experimental data.

At block 105, a SOC lower limit value (SOC_1) can be obtained according to the calculated OCV lower limit value and the established correlation table.

At block 106, a SOH value at the moment can be calculated by a relationship of SOH=100%−SOC_1. Therefore, the estimating SOH of a battery can be completed.

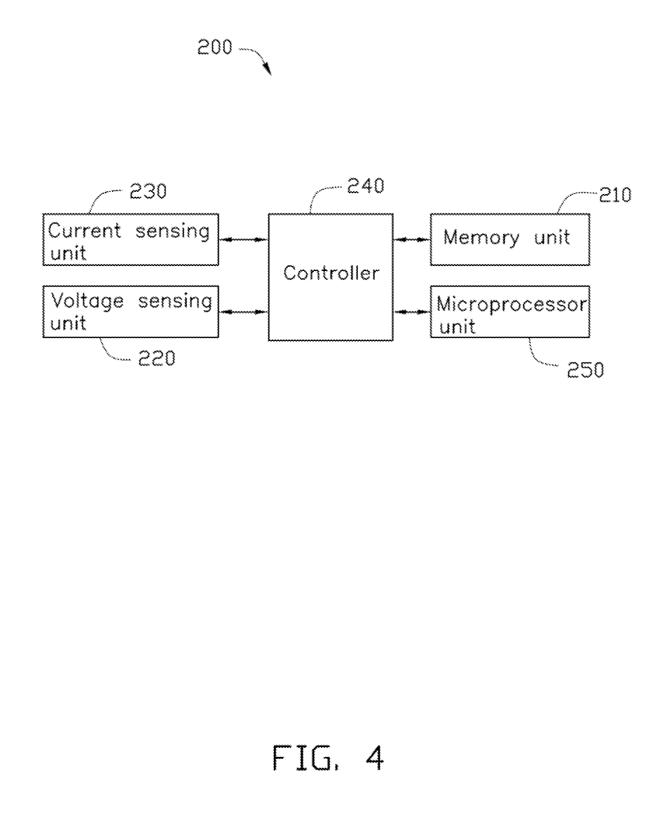

FIG. 4 illustrates that an apparatus of estimating SOH of a battery 200. The apparatus of estimating SOH of the battery 200 can include a memory unit 210, a voltage sensing unit 220, a current sensing unit 230, a controller 240, and a microprocessor unit 250. The controller 240 can control the memory unit 210, the voltage sensing unit 220 and the current sensing unit 230.

The memory unit 210 can store the correlation table of the OCV value and the SOC.

The voltage sensing unit 220 and current sensing unit 230 can measure current and voltage of a battery according to the control of the controller 240, and makes it possible to calculate the internal resistance of a battery. In general, the internal resistance of the battery is to sum up impedance such as a direct current (DC) resistance, or a spreading resistance etc., and is difficult to measure in real time. For this reason, it is good to measure only a component of pure DC resistance. It is preferable to measure the resistance within a rapid time period, but the measurement time is arbitrarily set to one second in consideration of hardware and a calculation time of other information.

When estimating SOH of a battery, the controller 240 can control the voltage sensing unit 220 and the current sensing unit 230 to measure a voltage and a current of the battery at the moment. The measured voltage and current can be transmitted to the microprocessor unit 250 via the controller 240. Simultaneously, the controller 240 can control the memory unit 210 to transmit the correlation table to the microprocessor unit 250.

The internal resistance of the battery can be calculated via the microprocessor unit 250 according to the measured voltage and current. A ΔV value of the battery can be calculated via the microprocessor unit 250 according to the calculated internal resistance. An OCV lower limit value can be calculated via the microprocessor unit 250 according to the calculated the ΔV. A SOC lower limit value (SOC_1) can be obtained via the microprocessor unit 250 according to the calculated OCV lower limit value and the established correlation table in the memory unit 210. The SOH value can be calculated via the microprocessor unit 250 according to the calculated SOC_1.

The apparatus of SOH of the battery 200 which can be combined with the method of estimating SOH of the battery will now be described. When SOH estimation is requested, the controller 240 can obtain a voltage and a current of a battery via the voltage sensing unit 220 and the current sensing unit 230. The measured voltage and current can be transmitted to the microprocessor unit 250 via the controller 240. The internal resistance of the battery can be calculated via microprocessor unit 250 according to the measured voltage and current (101).

A ΔV value of the battery can be calculated via the microprocessor unit 250 according to the calculated internal resistance (102).

An OCV lower limit value can be calculated via the microprocessor unit 250 according to the calculated ΔV (103).

A SOC lower limit value (SOC_1) can be obtained via the microprocessor unit 250 according to the calculated OCV lower limit value and the established correlation table in the memory unit 210 (104, 105).

The SOH value can be calculated via the microprocessor unit 250 according to the calculated SOC_1 (106).

As described above, the SOH of the battery can be directly estimated by the relationship of the measured internal resistance and the OCV. The method of estimating SOH of the battery is simple, and the apparatus of estimating SOH of the battery is cost effective.

The embodiments shown and described above are only examples. Many details are often found in the art such as the other features of a method and an apparatus of estimating SOH of a battery. Therefore, many such details are neither shown nor described. Even though numerous characteristics and advantages of the present technology have been set forth in the foregoing description, together with details of the structure and function of the present disclosure, the disclosure is illustrative only, and changes may be made in the details, including in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A method of estimating state of health (SOH) of a battery comprising:
measuring an internal resistance (R) of a battery;
calculating a voltage drop (ΔV) value by a relationship of ΔV=R×I, the current (I) value is equal to a preset current lower limit value at the available capacity;
calculating an open circuit voltage (OCV) lower limit value according to the calculated ΔV value at the available capacity;
obtaining a state of charge lower limit (SOC_1) value according to the calculated OCV lower limit value and the correlation table of an OCV value and a SOC; and
calculating a SOH value at the moment by a relationship of SOH=100%−SOC_1 according to the obtained SOC_{—}1 value.

2. The method of estimating SOH of the battery as claimed in claim 1, wherein the internal resistance of the battery is calculated via measuring a voltage and a current of the battery.

3. The method of estimating SOH of the battery as claimed in claim 1, wherein the OCV lower limit value is calculated via adding the ΔV and a voltage lower limit (V) at the available capacity.

4. The method of estimating SOH of the battery as claimed in claim 1, wherein the correlation table of the OCV value and the SOC as following:

| OCV(V) | SOC |
|---|---|
| 4.1833 | 100% |
| 4.0852 | 90% |
| 4.0024 | 80% |
| 3.9342 | 70% |
| 3.8702 | 60% |
| 3.8072 | 50% |
| 3.7808 | 40% |
| 3.772 | 30% |
| 3.749 | 20% |
| 3.6437 | 10% |
| 3.2809 | 0% |

5. An apparatus of estimating state of health (SOH) of a battery comprising:
a memory unit storing the correlation table of an open circuit voltage (OCV) value and a SOC;
a voltage sensing unit measuring a voltage of a battery;
a current sensing unit measuring a current of the battery;
a controller controlling the memory unit, the voltage sensing unit and the current sensing unit; and
a microprocessor unit measuring an internal resistance (R) of the battery, a voltage drop (ΔV) value according to the measured R, an OCV lower limit value according to the measured ΔV value, a state of charge lower limit (SOC_1) value according to the OCV lower limit value, and a SOH value according to the SOC_{—}1 value; the microprocessor unit reads the correlation table of the OCV value and the SOC from the memory unit.

6. The apparatus of estimating SOH of the battery as claimed in claim 5, wherein the correlation table of the OCV value and the SOC as following:

| OCV(V) | SOC |
|---|---|
| 4.1833 | 100% |
| 4.0852 | 90% |
| 4.0024 | 80% |
| 3.9342 | 70% |
| 3.8702 | 60% |
| 3.8072 | 50% |
| 3.7808 | 40% |
| 3.772 | 30% |
| 3.749 | 20% |
| 3.6437 | 10% |
| 3.2809 | 0% |

7. The apparatus of estimating SOH of the battery as claimed in claim 5, wherein the controller controls the voltage sensing unit and the current sensing unit measure a voltage and a current of the battery at the moment respectively.

8. The apparatus of estimating SOH of the battery as claimed in claim 5, wherein the controller transmits the measured voltage and current to the microprocessor unit.

9. The apparatus of estimating SOH of the battery as claimed in claim 5, wherein the controller transmits the correlation table of the OCV value and the SOC from the memory unit to the microprocessor unit.
